(19) United States
(12) Patent Application Publication
(10) Pub. No.: US 2015/0262640 A1
(43) Pub. Date: Sep. 17, 2015

(54) MEMORY SYSTEM

(71) Applicant: Akira KATAYAMA, Seoul (KR)

(72) Inventor: Akira KATAYAMA, Seoul (KR)

(21) Appl. No.: 14/482,947

(22) Filed: Sep. 10, 2014

Related U.S. Application Data
(60) Provisional application No. 61/951,440, filed on Mar. 11, 2014.

(51) Int. Cl. G11C 11/16; G11C 29/52; G06F 11/10

(52) U.S. Cl. CPC G11C 11/1675; G11C 11/1673; G06F 11/1068; G11C 29/52

(57) ABSTRACT

According to one embodiment, a memory system includes a first memory cell array and a second memory cell array; and a control circuit controls data of the first and second memory cell arrays. The control circuit sets, when receiving an initialization instruction, all of the plurality of bits of the first memory cell array at a first value, and sets all of the plurality of bits of the second memory cell array at a second value which is a complementary value of the first value.

### CROSS REFERENCE TO RELATED APPLICATIONS

This application claims the benefit of U.S. Provisional Application No. 61/951,440, filed Mar. 11, 2014, the entire contents of which are incorporated herein by reference.

### FIELD

Embodiments described herein relate generally to a semiconductor memory device.

### BACKGROUND

There is known a magnetic random access memory (MRAM) as one of resistance change type memories. Writing methods of MRAMs include a magnetic field writing method and a spin transfer writing method. Of these methods, the spin transfer method is advantageous in increasing an integration density, reducing power consumption and enhancing capabilities, since this method has such a characteristic that a spin transfer current that is necessary for magnetization reversal decreases as the size of a magnetic body becomes smaller.

An MTJ (Magnetic Tunnel Junction) element of the spin transfer writing method has a multilayer structure which is composed of two ferromagnetic layers and a nonmagnetic barrier layer (insulation thin film) interposed therebetween, and digital data is stored by a change in magnetic resistance due to a spin polarization tunnel effect. The MTJ element may take a low resistance state and a high resistance state by a magnetization orientation of the two ferromagnetic layers. When the magnetization orientation (spin direction) of the two ferromagnetic layers is in a parallel state (P (Parallel) state), the MTJ element is in the low resistance state. When the magnetization orientation of the two ferromagnetic layers is in an antiparallel state (AP (AntiParallel) state), the MTJ element is in the high resistance state.

### BRIEF DESCRIPTION OF THE DRAWINGS

FIG. 1 is a block diagram illustrating a structure of a memory system according to an embodiment.

FIG. 2 is a block diagram illustrating a structure of a semiconductor memory device according to the embodiment.

FIG. 3 is a view illustrating a structure of a memory cell array according to the embodiment.

FIG. 4 is a view illustrating a write operation of a memory cell according to the embodiment.

FIG. 5 is a block diagram illustrating a structure of a sense amplifier and the memory cell array according to the embodiment.

FIG. 6 is a block diagram illustrating a structure of the sense amplifier and memory cell array according to the embodiment.

FIG. 7 is a block diagram illustrating a structure of the sense amplifier and memory cell array according to the embodiment.

FIG. 8 is a block diagram illustrating a structure of the sense amplifier and memory cell array according to the embodiment.

FIG. 9 is a block diagram illustrating a structure of the sense amplifier and memory cell array according to the embodiment.

FIG. 10 illustrates a command sequence of a write operation of the memory system according to the embodiment.

FIG. 11 is a view illustrating a state of data at a time of a write operation of the memory system according to the embodiment.

FIG. 12 is a view illustrating a state of data at a time of a write operation of the memory system according to the embodiment.

### DETAILED DESCRIPTION

In general, according to one embodiment, a semiconductor memory device includes a first memory cell array and a second memory cell array each configured to be able to store data of a plurality of bits, and a control circuit configured to control data of the first and second memory cell arrays. The control circuit is configured to set, when receiving an initialization instruction, all of the plurality of bits of the first memory cell array at a first value, and to set all of the plurality of bits of the second memory cell array at a second value which is a complementary value of the first value.

Hereinafter, embodiments, which have been constructed, will be described with reference to the accompanying drawings. In the description below, structural elements having substantially the same functions and structures are denoted by like reference signs, and an overlapping description is given only where necessary. The “alphabet” or “hyphen & numeral” after a numeral, which constitutes a reference sign, and the “numeral” or “hyphen & numeral” after a symbol, which constitutes a reference sign, are used in order to distinguish elements which are referred to by reference signs including the same numeral and have the same structure. When it is not necessary to distinguish elements which are indicated by reference signs including the same numeral, these elements are referred to by a reference sign including only a numeral or a symbol. For example, when it is not necessary to distinguish elements with reference signs 1a and 1b, these elements are comprehensively referred to by a reference sign 1. In addition, for example, when it is not necessary to distinguish elements with reference signs WL1 and WL2, these elements are comprehensively referred to by a reference sign WL.

It should be noted that the drawings are schematic ones, and the relationship between a thickness and a planar dimension, the ratio in thickness between layers, etc. are different from real ones. Thus, concrete thicknesses and dimensions should be judged in consideration of descriptions below. Needless to say, the drawings include parts with mutually different relations or ratios of dimensions. Besides, embodiments to be described below illustrate, by way of example, devices or methods for embodying technical concepts of the embodiments, and the technical concepts of the embodiments do not specifically restrict the material, shape, structure, arrangement, etc. of structural components to those described below. Various changes may be made in the technical concepts of the embodiments within the scope of the claims.

In embodiments to be described below, an MRAM (Magnetic Random Access Memory) is described as an example of the semiconductor memory device.

### Embodiment

### Structure of a Memory System According to an Embodiment

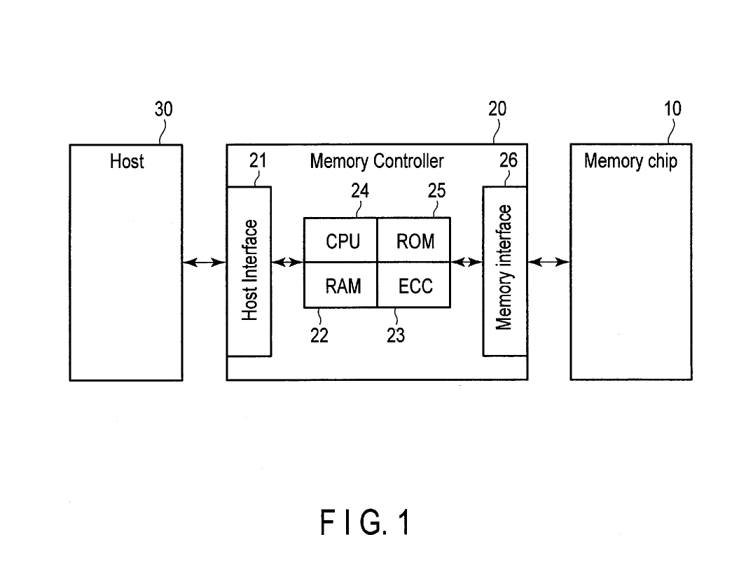

To begin with, referring to FIG. 1, a basic structure of a memory system according to an embodiment is schematically described.

A memory system 100 includes a memory chip (semiconductor memory device) 10 and a memory controller 20.

The memory controller 20 includes a host interface 21, a RAM (Random Access Memory) 22, an ECC (Error Correcting Code) circuit (also referred to as an error correcting circuit, etc.) 23, a CPU (Central Processing unit) 24, a ROM (Read Only Memory) 25, and a memory interface 26.

The memory controller 20 outputs commands, etc., which are necessary for the operation of the memory chip 10, to the memory chip 10, reads data from the memory chip 10, and executes write of data in the memory chip 10 or erase of data of the memory chip 10.

The host interface 21 is connected to a host device (external device) 30, such as a personal computer, via a data bus. Transmission/reception of data is executed between the host device 30 and the memory system 100 via the host interface 21.

The RAM 22 is a volatile memory, and stores an operation program, etc. for the operation of, for example, the CPU 24.

The ECC (Error Correcting Code) circuit 23 receives write data from the host device 30, adds an error correcting code to the write data, and supplies the write data, to which the error correcting code has been added, to, for example, the memory interface 26. In addition, when the ECC circuit 23 receives a data mask at a time of a write operation, data corresponding to the data mask is read out from the memory chip 10 by the CPU 24, etc. From the write data received from the host device 30 and the data read out from the memory chip 10, the ECC circuit 23 calculates an error correcting code, and adds the error correcting code to the write data. Furthermore, the ECC circuit 23 receives data, which has been supplied from the memory chip 10, via the memory interface 26, and executes error correction for this data by using the error correcting code.

The CPU (Central Processing unit) 24 controls the overall operation of the memory system 100. The CPU 24 controls the memory chip 10, based on data stored in the RAM 24 and ROM 25.

The ROM (Read Only Memory) 25 is a nonvolatile memory, and stores an operation program, etc. for the operation of, for example, the CPU 24.

The memory chip 10 is connected to the memory interface 26 via a data bus.

<Structure of a Semiconductor Memory Device According to the Embodiment>

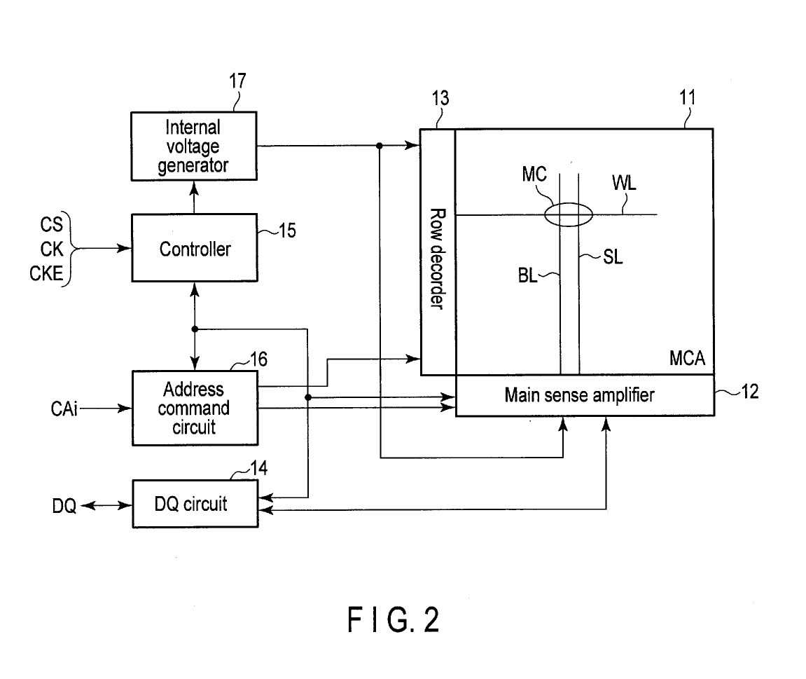

Next, referring to FIG. 2, a basic structure of a semiconductor memory device according to the embodiment is schematically described.

As illustrated in FIG. 2, the memory chip 10 according to the embodiment includes a memory cell array (also referred to simply as “cell array”) 11, a main sense amplifier 12, a row decoder 13, a DQ circuit 14, a controller 15, an address command circuit 16, and an internal voltage generator 17.

The memory cell array 11 is an MRAM, in which a plurality of memory cells MC are arranged two-dimensionally in a matrix. Each memory cell MC includes an MTJ (Magnetic Tunnel Junction) element 42 (not shown) and a cell transistor 43 (not shown). The MTJ element 42 is a magnetic tunnel junction element which stores data by a change in resistance state, and can rewrite data by an electric current. The cell transistor 43 is provided in association with the MTJ element 42, and is configured to be rendered conducive when a current is caused to flow in the associated MTJ element 42.

A plurality of word lines WL are arranged in a row direction and a plurality of bit lines BL are arranged in a column direction such that the word lines WL and bit lines BL cross each other. Two neighboring bit lines BL constitute a pair, and the memory cell MC is provided in association with an intersection between the word line WL and the bit line pair (in this embodiment, for convenience′ sake, referred to as a bit line BL and a source line SL). The MTJ element 42 and cell transistor 43 of each memory cell MC are connected in series between the bit line pair (e.g. between BL and SL). In addition, the gate of the cell transistor 43 is connected to the word line WL.

The main sense amplifier 12 is disposed in a bit line direction of the memory cell array 11, and recognizes, based on an external control signal, a command or an address by a command by a command address signal CAi, and controls the bit line BL and source line SL.

The main sense amplifier 12 is connected to the bit line BL, and reads out data stored in the memory cell by sensing a current flowing in the memory cell MC which is connected to the selected word line WL. In addition, the main sense amplifier 12 includes a write driver. The write driver writes data by causing a current to flow in the memory cell MC which is connected to the selected word line WL.

Besides, when receiving a twin/single selection signal, the main sense amplifier 12 causes the memory cell array 11 to operate in a single cell mode or a twin cell mode. Incidentally, the single cell mode and twin cell mode will be described later.

The transmission/reception of data between the sense amplifier 12 and an external input/output terminal DQ is executed via the DQ circuit 14.

The row decoder 13 is disposed on each of both sides in the word line direction of the memory cell array 11, and decodes an address of the command address signal CAi which has been supplied from the address command circuit 16.

In addition, the row decoders 13 are disposed on both sides in the word line direction of the memory cell array 11 and connected to the word lines, and are configured to apply a voltage to the selected word line WL at a time of data read or data write. More specifically, the row decoder 13 is configured to apply a voltage to the selected word line WL, in accordance with a decoded row address.

Various external control signals, for instance, a chip select signal CS, a clock signal CK and a clock enable signal CKE, are input to the controller 15. The controller 12 controls the address command circuit 16, and discriminates an address and a command.

A command address signal CAi is input to the address command circuit 16. The address command circuit 16 transfers the command address signal CAi to the row decoder 13 and main sense amplifier 12.

The internal voltage generator 17 is provided in order to generate an internal voltage (e.g. a voltage boosted by a power supply voltage) which is necessary for operations in the memory chip 10. This internal voltage generator 17, too, is controlled by the controller 15, and executes a boost operation and generates a necessary voltage.

<Memory Cell Array>

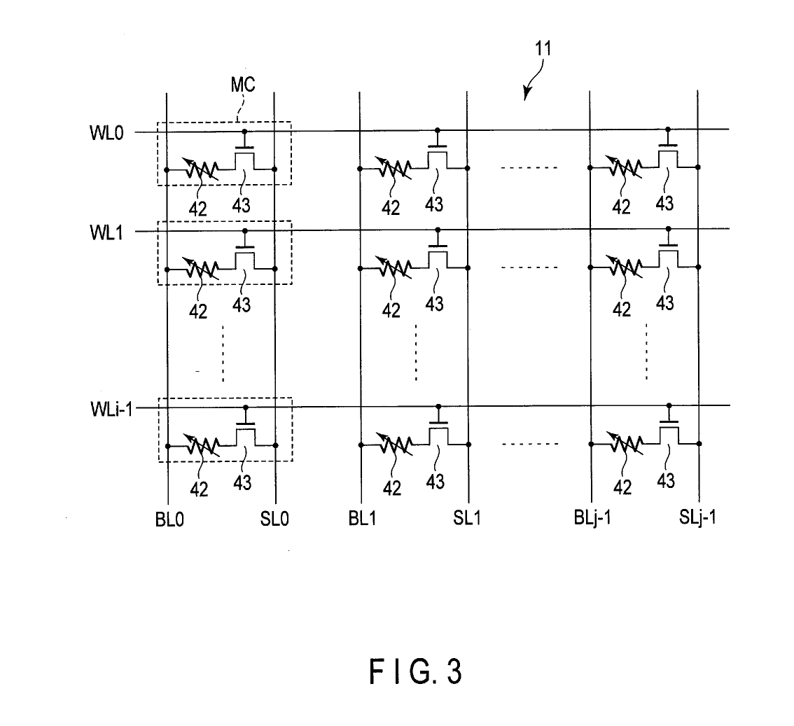

Next, referring to FIG. 3, a description is given of the structure of the memory cell array 11 according to the embodiment. As described above, the memory cell array 11 is configured such that a plurality of memory cells MC are arranged in a matrix. In the memory cell array 11, a plurality of word lines WL0 to WLi−1, a plurality of bit lines BL0 to BLj−1, and a plurality of source lines SL0 to SLj−1 are disposed. One row of the memory cell array is connected to one word line WL, and one column of the memory cell array is connected to a pair composed of one bit line BL and one source line SL. Incidentally, in the memory cell array 11, write of data is executed by a unit called “page”.

<Write Operation of the Memory Cell MC>

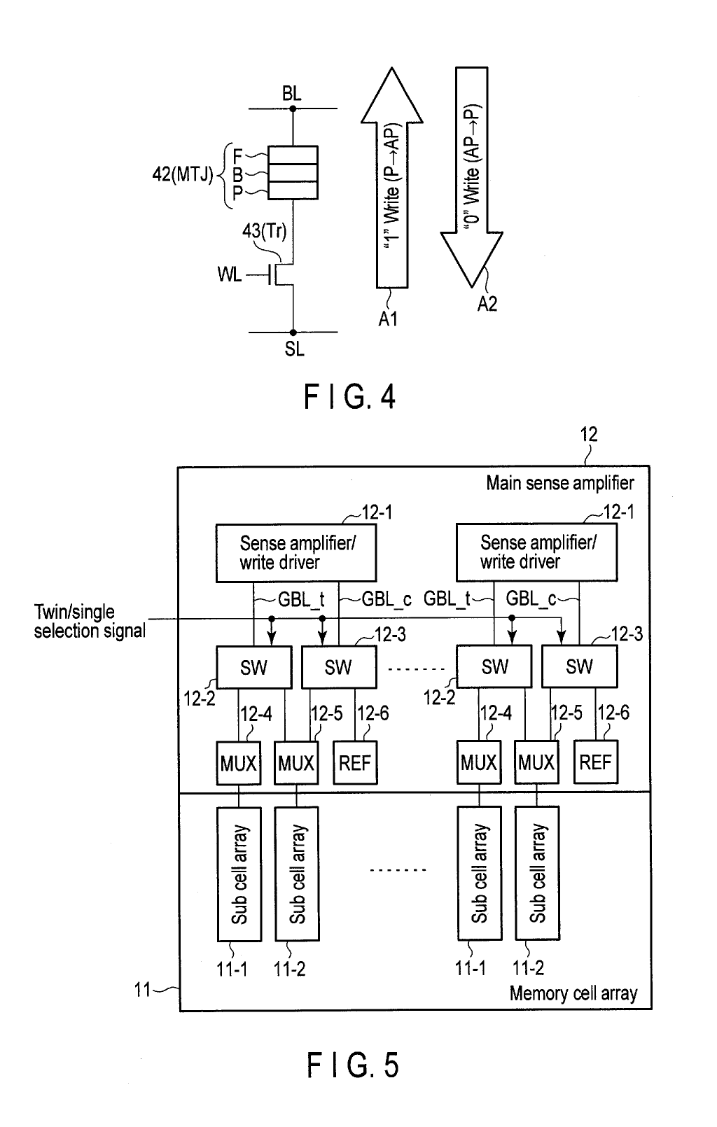

Next, referring to FIG. 4, a write operation of the memory cell MC according to the embodiment is schematically described. FIG. 4 is a view illustrating the write operation of the memory cell MC according to the embodiment.

As illustrated in FIG. 4, one end of an MTJ element 42 of the memory cell MC according to the embodiment is connected to the bit line BL, and the other end of the MTJ element 42 is connected to one end of a current path of a cell transistor 43. The other end of the current path of the cell transistor 43 is connected to the source line SL. The MTJ element 42, which makes use of a TMR (tunneling magnetoresistive) effect, has a multilayer structure which is composed of two ferromagnetic layers F, P and a nonmagnetic layer (tunnel insulation film) B interposed therebetween, and stores digital data by a change in magnetic resistance by a spin polarization tunnel effect. The MTJ element 42 may take a low resistance state and a high resistance state by a magnetization orientation of the two ferromagnetic layers F, P. For example, if the low resistance state is defined as data “0” and the high resistance state is defined as data “1”, 1 bit data can be stored in the MTJ element 42. Needless to say, the low resistance state may be defined as data “1” and the high resistance state may be defined as data “0”.

For example, the MTJ element 42 is configured such that a fixed layer (pin layer) P, a tunnel barrier layer B and a recording layer (free layer) F are successively stacked. The pin layer P and free layer F are formed of a ferromagnetic material, and the tunnel barrier layer B is formed of an insulation film (e.g. Al₂O₃, MgO). The pin layer P is a layer with a fixed direction of magnetization orientation. The free layer F has a variable direction of magnetization orientation, and data is stored by the direction of magnetization.

If an electric current is caused to flow in a direction of arrow A1 at a time of write, the magnetization direction of the free layer F is set in an antiparallel state (AP state), relative to the magnetization direction of the pin layer P, and a high resistance state (data “1”) is set. If an electric current is caused to flow in a direction of arrow A2 at a time of write, the magnetization directions of the pin layer P and free layer F are set in a parallel state (P state), and a low resistance state (data “0”) is set. In this manner, in the MTJ element, different data can be written in accordance with the direction of flow of an electric current.

<Structure of the Memory Cell Array and Main Sense Amplifier According to the Embodiment>

Next, referring to FIG. 5, a layout of the cell array and main sense amplifier according to the embodiment is schematically described.

As illustrated in FIG. 5, the main sense amplifier 12 includes a plurality of sense amplifiers/write drivers 12-1. A first switch 12-2 is connected to each sense amplifier/write driver 12-1 via a global bit line GBL_t, and a second switch 12-3 is connected to each sense amplifier/write driver 12-1 via a global bit line GBL_c. In addition, a first multiplexer 12-4 and a second multiplexer 12-5 are connected to the first switch 12-2. Besides, the second multiplexer 12-5 and a reference circuit 12-6 are connected to the second switch 12-3.

The memory cell array 11 includes a plurality of first sub cell arrays 11-1 and second sub cell arrays 11-2. The plural first sub cell arrays 11-1 are connected to the first multiplexers 12-4, respectively. In addition, the plural second sub cell arrays 11-2 are connected to the second multiplexers 12-5, respectively.

When the first switches 12-2 is receiving a twin/single selection signal from the controller 15, the first switches 12-2 and second switches 12-3 control the connection between the sense amplifiers/write drivers 12-1, and the first sub cell arrays 11-1, second sub cell arrays 11-2 and reference circuits 12-6.

Specifically, when a “twin cell mode” is selected based on the twin/single selection signal, the first sub cell array 11-1 is connected to the sense amplifier/write driver 12-1 via the first multiplexer 12-4 and first switch 12-2, and the second sub cell array 11-2 is connected to the sense amplifier/write driver 12-1 via the second multiplexer 12-5 and second switch 12-3.

The twin cell mode is an operation mode in which sense of data is executed by using the sub cell array in place of the reference circuit 12-6. In the twin cell mode, when net data is stored in the sub cell array 11-1, inversion data of the sub cell array 11-1 is stored in the sub cell array 11-2. In other words, complementary data are stored in the sub cell array 11-1 and sub cell array 11-2, respectively. To be more specific, when “1” data is stored at a predetermined address of the sub cell array 11-1, “0” data, which is complementary data of “1”, is stored at an address of the sub cell array 11-2, which corresponds to this predetermined address. The sense amplifier/write driver 12-1 determines “0” data or “1” data, by sensing the complementary data of the sub cell array 11-1 and sub cell array 11-2. If the sub cell array 11-2 does not store the complementary data of the sub cell array 11-1, the sense amplifier/write driver 12-1 is unable to sense data. In such a case, a data read result is, for instance, “read is impossible” or “data is uncertain”.

In addition, when a “single cell mode” is selected based on the twin/single selection signal, the first sub cell array 11-1 is connected to the sense amplifier/write driver 12-1 via the first multiplexer 12-4 and first switch 12-2, and the reference circuit 12-6 is connected to the sense amplifier/write driver 12-1 via the second switch 12-3. Furthermore, when an “other single cell mode” is selected based on the twin/single selection signal, the second sub cell array 11-2 is connected to the sense amplifier/write driver 12-1 via the second multiplexer 12-5 and first switch 12-2, and the reference circuit 12-6 is connected to the sense amplifier/write driver 12-1 via the second switch 12-3.

<Read Operation Examples of the Memory System According to the Embodiment>

Next, a description is given of read operation examples in the respective operation modes of the system 100 according to the embodiment.

<Read Operation Example in the Single Cell Mode>

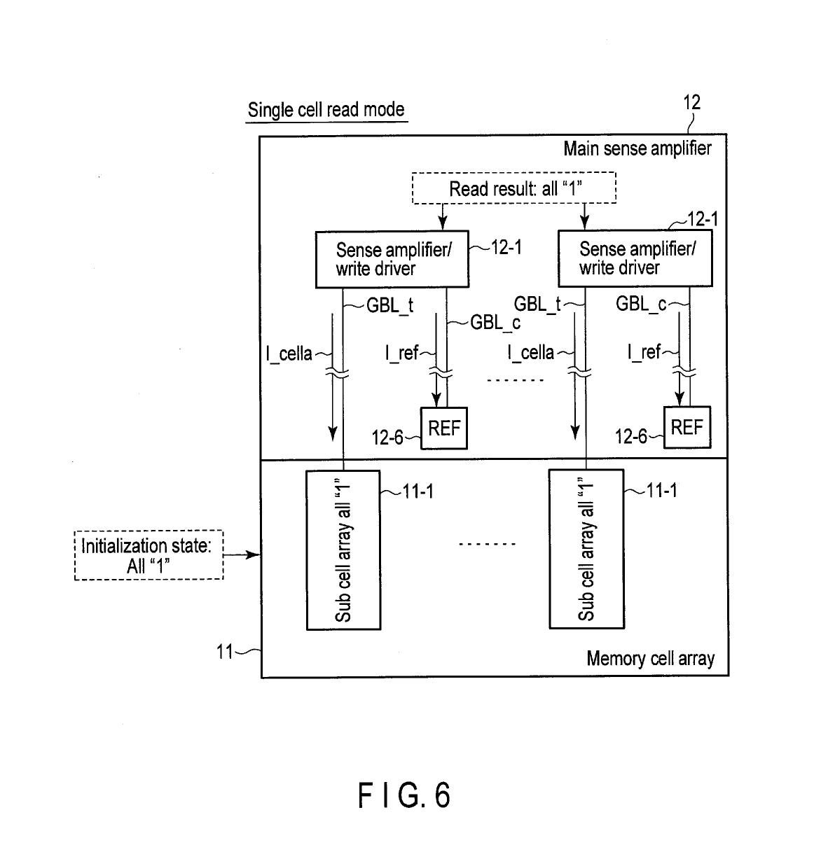

To begin with, referring to FIG. 6, a description is given of a read operation example in the single cell mode of the memory system according to the embodiment. For the purpose of simple description, the case of reading data of the sub cell array 11-1 is described. In addition, in this example, a description is given of the case in which the memory cell array 11 is in an initialization state (All “1”) of the single mode.

As illustrated in FIG. 6, the sense amplifier/write driver 12-1 reads out data of the sub cell array 11-1 by using the reference circuit 12-6. Specifically, by comparing a cell current I_cella flowing to the sub cell array 11-1 and a reference current I_ref flowing to the reference circuit 12-6, the sense amplifier/write driver 12-1 reads data stored in the sub cell array 11-1. In the case of this example, the sense amplifiers/write drivers 12-1 acquire a read result that all data stored in the sub cell arrays 11-1 are “1” (initialization state).

<Read Operation Example 1 in the Twin Cell Mode>

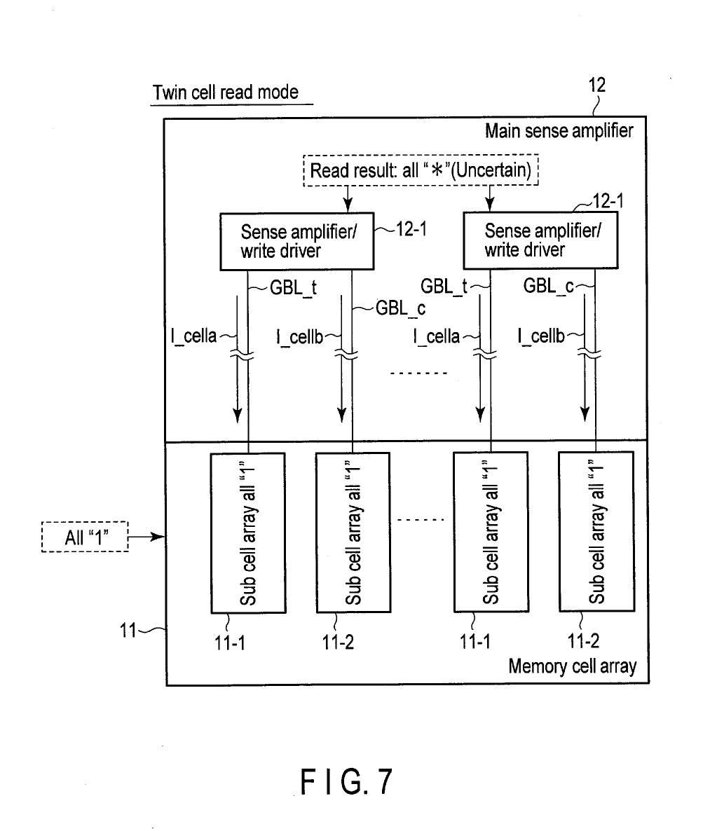

Next, referring to FIG. 7, a description is given of a read operation example 1 in the twin cell mode of the memory system according to the embodiment. In this example, a description is given of the case in which the memory cell array 11 is in an initialization state (All “1”) of the single mode.

As illustrated in FIG. 7, all data stored in the sub cell array 11-1 and the sub cell array 11-2 are “1”. The sense amplifier/write driver 12-1 reads out data of the sub cell array 11-1 by using the data of the sub cell array 11-2. Specifically, by comparing a cell current I_cella flowing to the sub cell array 11-1 and a cell current I_cellb flowing to the sub cell array 11-2, the sense amplifier/write driver 12-1 reads data stored in the sub cell array 11-1. In the case of this example, the data stored in the sub cell array 11-1 and the data stored in the sub cell array 11-2 are identical. Thus, the cell current I_cella and the cell current I_cellb are the same current. Thereby, the sense amplifier/write driver 12-1 is unable to read data of the sub cell array 11-1. As a result, a read result of the sense amplifier/write driver 12-1 is, for instance, “read is impossible” or “data is uncertain” (expressed by “*”).

<Read Operation Example 2 in the Twin Cell Mode>

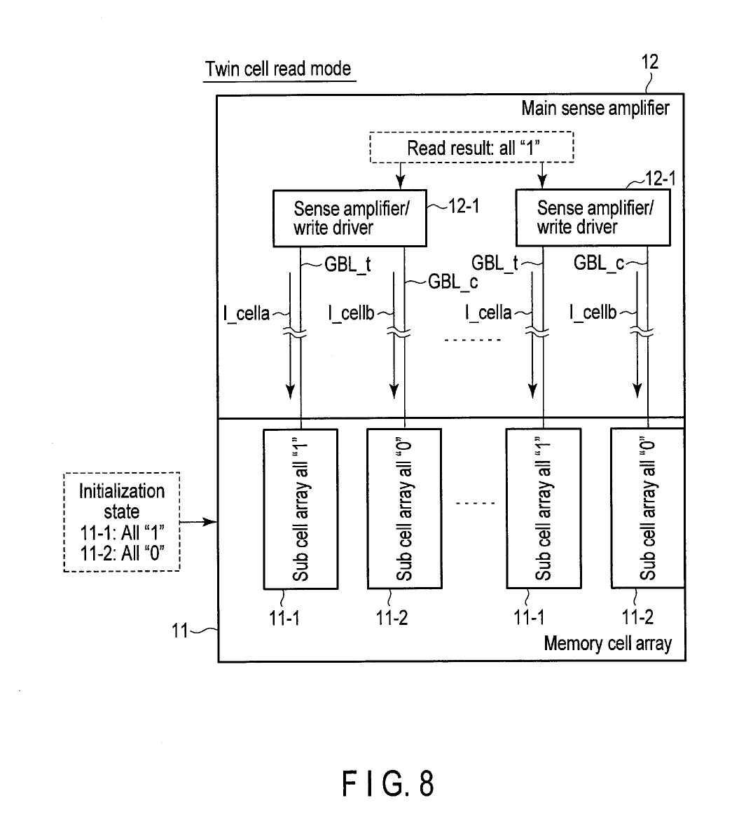

Next, referring to FIG. 8, a description is given of a read operation example 2 in the twin cell mode of the memory system according to the embodiment.

In the twin cell mode, when the memory cell array 11 is set in the initialization state, as shown in FIG. 8, the memory controller 20 sets all data of sub cell arrays 11-1 to be “1” data, and sets all data of sub cell arrays 11-2 to be “0” data.

The sense amplifier/write driver 12-1 reads out data of the sub cell array 11-1 by using the data of the sub cell array 11-2. Specifically, by comparing a cell current I_cella flowing to the sub cell array 11-1 and a cell current I_cellb flowing to the sub cell array 11-2, the sense amplifier/write driver 12-1 reads data stored in the sub cell array 11-1. In the case of this example, the sense amplifier/write driver 12-1 outputs a read result that all data stored in the sub cell arrays 11-1 are “1” (initialization state).

<Initializing Method in the Twin Cell Mode>

In the meantime, as an initializing method of a semiconductor memory device using an MRAM, there is known a method in which initialization is executed by making identical the directions of magnetization orientation of the free layers F of all variable resistance elements of the memory cell array 11, by approaching a magnet. However, as described with reference to FIG. 7, in the twin cell mode, in the twin cell mode, if the directions of magnetization orientation of the free layers F of all variable resistance elements of the memory cell array 11 are made identical, there arises such a problem that data read cannot correctly be executed. In the case of realizing initialization in the twin cell mode, as described with reference to FIG. 8, it is necessary that complementary data of the sub cell array 11-1 be written in the sub cell array 11-2.

Specifically, initialization that is suited to the twin cell mode cannot be realized by the initialization which simply uses the magnet.

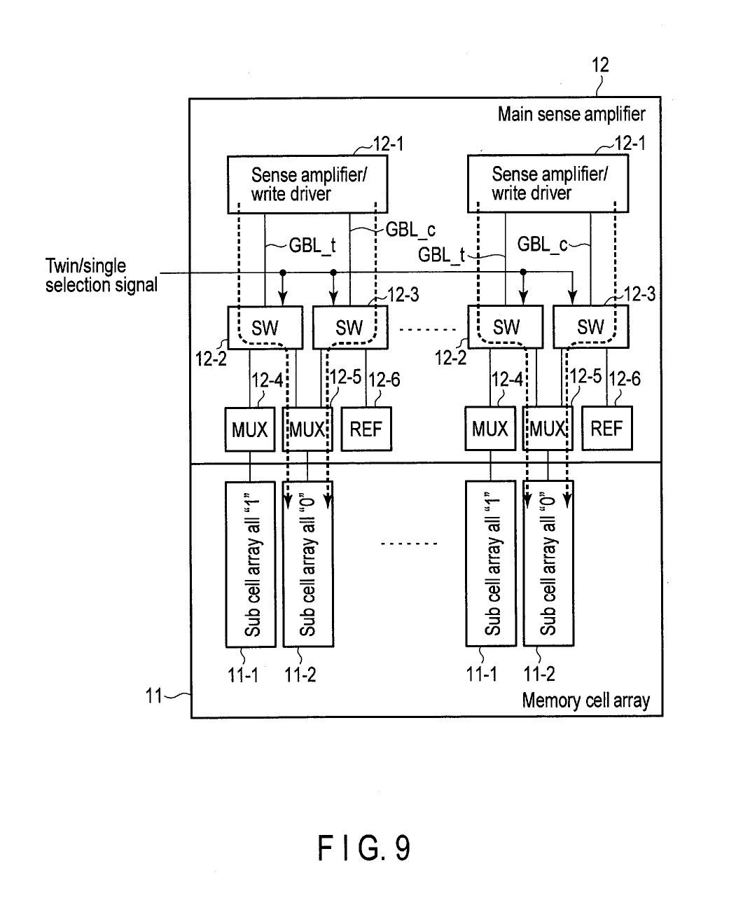

Taking the above into account, with reference to FIG. 9, a description is given of an initialization method in the twin cell mode of the memory system according to the embodiment.

To begin with, like the initialization of the single cell mode, all data in the memory cell array 1 are set in the “1” state by using a magnet. Then, the memory controller 20 issues an initialization write signal (for the twin cell mode) to the memory chip 10. Thereby, the controller 15 controls the main sense amplifier 12 so as to set all data in one of the paired sub cell arrays used in the twin cell mode in the “0” state.

As illustrated in FIG. 9, the controller 15 supplies a twin/single selection signal to the first switch 12-2 and second switch 12-3. Thereby, the sub cell array 11-2 is connected to the sense amplifier/write driver 12-1 via the multiplexer 12-5 and first switch 12-2. Then, the sense amplifier/write driver 12-1 writes “0” data in the sub cell array 11-2, based on the control of the controller 15.

In addition, as illustrated in FIG. 9, the controller 15 may connect the amplifier/write driver 12-1 and the sub cell array 11-2 via the multiplexer 12-5 and second switch 12-3. Then, the controller 15 may write “0” data in the sub cell array 11-2 by using the sense amplifier/write driver 12-1.

Thereby, “1” data is stored in the sub cell array 11-1, and “0” data is stored in the sub cell array 11-2. Thus, the initialization operation in the twin cell mode is completed.

<Write Operation Example of the Memory System According to the Embodiment>

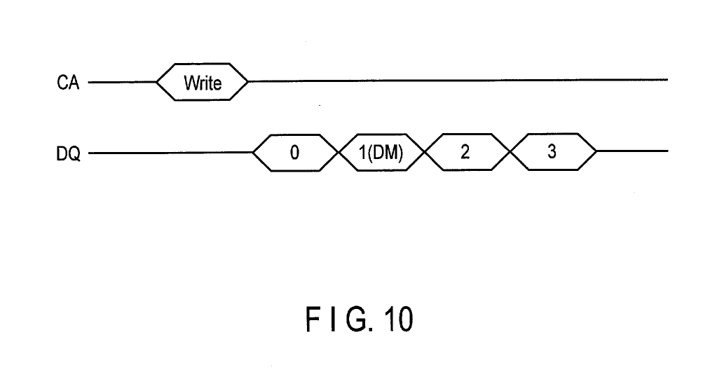

Next, referring to FIG. 10 to FIG. 12, a description is given of a write operation of the memory system 100 according to the embodiment.

As illustrated in FIG. 10, at a time of the write operation of the memory system 100 according to the embodiment, the memory chip 10 receives a write command at the address command circuit 16, and subsequently receives write data 0, 1 (DM) and 3 via the DQ circuit 14. In this case, it is assumed that write data 1 is a data mask. The data mask means no execution of a write operation on a target memory cell.

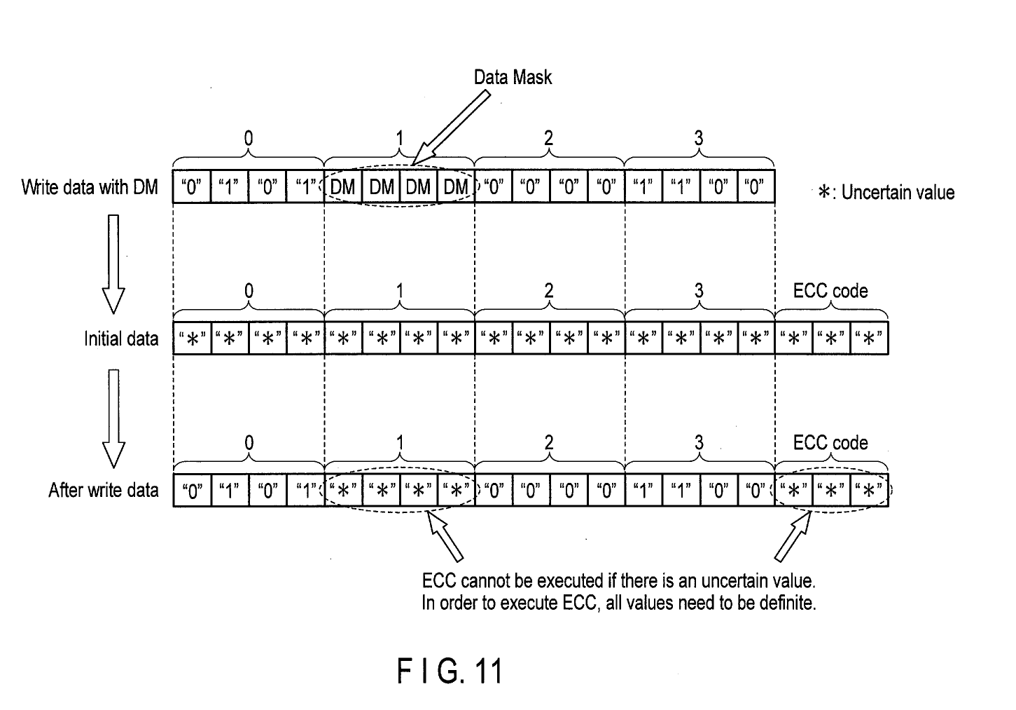

Next, referring to FIG. 11, a description is given of a write operation of the memory system 100 in a case where the memory cell array 11 fails to be normally initialized, as illustrated in FIG. 7.

As illustrated in FIG. 11, when all memory cells MC of the memory cell array 11 have “1” data in the initial state, it is determined by the sense amplifier/write driver 12-1 that all data are uncertain values (“*”). At this time, the ECC also becomes an uncertain value (“*”).

The memory system 100 executes write of write data 0 to 3 for the initial values. As described above, write data 1 is a data mask.

At the time of the write operation of data, in order to calculate the ECC, the ECC circuit 23 needs to read out data of an area for which the data mask is executed.

However, since the data of the area, for which the data mask is executed, is in the uncertain state, the ECC circuit 23 cannot calculate the ECC.

Thus, when a write operation is executed for the memory cell array 11 in which uncertain data exists, the ECC circuit 23 cannot add an ECC to the write data relating to this write operation. As a result, when the write data has been read out, the ECC circuit 23 cannot execute a correction with use of the ECC.

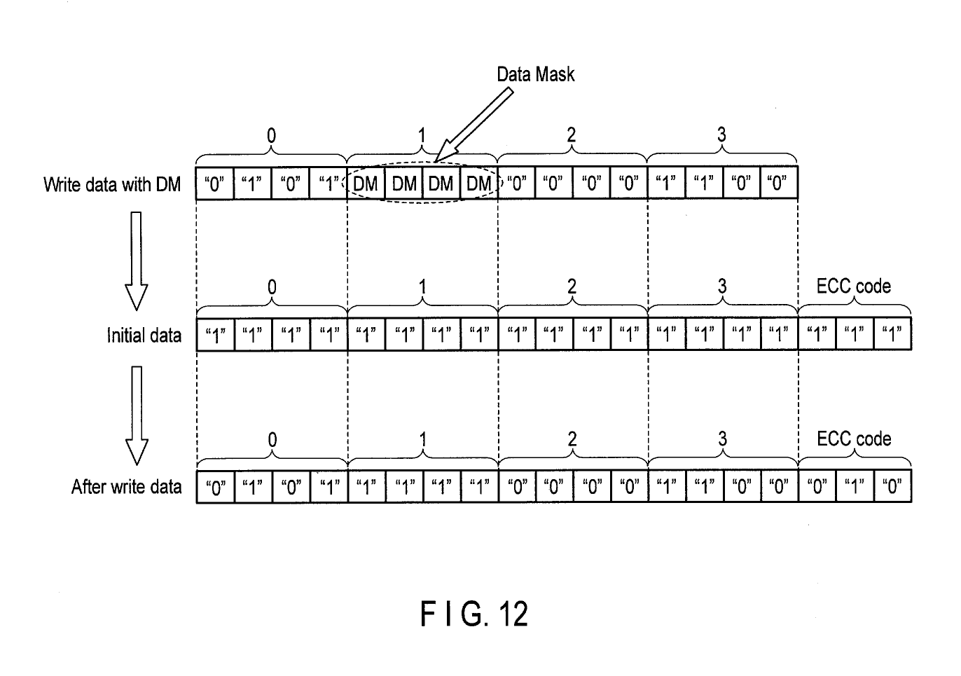

Next, referring to FIG. 12, a description is given of a write operation of the memory system 100 in a case where the memory cell array 11 is normally initialized, as illustrated in FIG. 8.

As illustrated in FIG. 12, the memory system 100 executes write of write data 0, 1, 2 and 3 for the memory cell array 11 having the initial values. As described above, write data 1 is a data mask.

At the time of the write operation of data, in order to calculate the ECC, the ECC circuit 23 needs to read out data of an area for which the data mask is executed.

In this example, unlike the operation example described with reference to FIG. 11, “1” data can be read from the area for which the data mask is executed. Thus, the ECC circuit 23 can calculate the ECC by using the write data 0, 2 and 3 and the initial values which have been read from the memory cell array 11. Thereby, the ECC circuit 23 can add an ECC to the write data relating to this write operation. As a result, when the write data has been read out, the ECC circuit 23 can execute a correction with use of the ECC.

<Advantageous Effects According to the Embodiment>

According to the above-described embodiment, when the memory chip 10 is to be initialized, the memory controller 20 first sets all data of the memory cell array 11 to be identical data. Then, the controller 15 writes data, which is complementary to that data, in only one of the paired sub cell arrays which are used in the twin cell mode. In the meantime, in FIG. 9, in the twin cell mode, the initialization operation (for the twin cell mode) has been executed so that data can be normally read out. However, even in the case where the initialization is executed on the presupposition of the use in the twin cell mode, it is possible to select and use the memory system 100 in the single cell mode.

As described above, in the single cell mode, the data stored in the memory cell array 11 is read out by using the reference circuit 12-6. As has been described with reference to FIG. 11, when the data is uncertain in the initial value state, there is a case in which a correction with use of an ECC cannot be executed. However, in the single cell mode, unlike the twin cell mode, data does not become uncertain due to the data stored in the sub cell array. Thus, if the initialization for the twin cell mode has been executed, the twin cell mode and the single cell mode can be properly selected and used.

Hence, the memory controller 20 executes the initialization operation on the presupposition of the above-described twin cell mode. Thereby, it becomes possible to provide a high-quality memory system which can properly select either the twin cell mode or the single cell mode, and can execute an error correction with the proper use of the ECC.

(Modifications, Etc.)

Incidentally, the number of the above-described sub cell arrays, and the numbers of switches, multiplexers, etc. are merely examples, and these numbers can be variously changed.

In the above-described embodiment, when the initialization operation is executed in the single cell mode, all data in the memory cell array 11 are set to be “1” data, but the embodiment is not limited to this example. For example, at the time of the initialization operation, all data in the memory cell array 11 may be set to be “0” data.

In addition, in the above-described embodiment, when the initialization operation is executed in the twin cell mode, all data in the sub cell array 11-1 are set to be “1” data and all data in the sub cell array 11-2 are set to be “0” data, but the embodiment is not limited to this example. For example, at the time of the initialization operation, all data in the sub cell array 11-1 may be set to be “0” data and all data in the sub cell array 11-2 are set to be “1” data.

In the above-described embodiment, when the operation mode of the memory chip 10 is switched from the single cell mode to the twin cell mode, the controller 15 initializes the memory chip 10. In addition, when the operation mode of the memory chip 10 is switched from the twin cell mode to the single cell mode, the controller 15 also initializes the memory chip 10. When such an initialization operation is to be executed, the initialization operation as described above is executed.

In the above-described embodiment, the example in which the ECC circuit 23 is included in the memory controller 20 has been described. However, the embodiment is not limited to this example. For example, the ECC circuit 23 may be included in the memory chip 10.

In the above-described embodiment, the MRAM has been described as the memory device by way of example. However, the embodiment can also be implemented as any other resistance change type memory including the same elements as illustrated in the above-described embodiment, for example, an FeRAM (Ferroelectric random access memory), a PCRAM (phase change random access memory), or a ReRAM (resistive random access memory).

Besides, in the above-described embodiment, the bit line pair has been referred to as the bit line BL and source line SL, for convenience's sake. However, the embodiment is not limited to this example, and the bit line pair may be referred to, for example, as a first bit line and a second bit line.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A memory system comprising:
a first memory cell array and a second memory cell array each configured to be able to store data of a plurality of bits; and
a control circuit which controls data of the first and second memory cell arrays,
wherein the control circuit sets, when receiving an initialization instruction, all of the plurality of bits of the first memory cell array at a first value, and sets all of the plurality of bits of the second memory cell array at a second value which is a complementary value of the first value.

2. The memory system of claim 1, further comprising a sense amplifier/write driver which senses, in accordance with control of the control circuit, the data stored in the first memory cell array and the second memory cell array, and the sense amplifier/write driver which writes data in the first memory cell array and the second memory cell array.

3. The memory system of claim 2, wherein in an initialization operation of the first and second memory cell arrays, the control circuit sets all of the plurality of bits of the first and second memory cell arrays at the first value, and to set all of the plurality of bits of the second memory cell array at the second value via the sense amplifier/write driver, after sets all of the plurality of bits of the first and second memory cell arrays at the first value.

4. The memory system of claim 3, wherein an operation of setting all of the plurality of bits of the first and second memory cell arrays at the first value is executed by using a magnet.

5. The memory system of claim 2, further comprising an error correcting circuit which generates an error correcting code, based on write data which is written in the first and second memory cell arrays, and to supply the data and the error correcting code to the sense amplifier/write driver.

6. The memory system of claim 5, wherein in a case where a data mask for executing no write operation of data at a predetermined area of the first and second memory cell arrays is included in the write data at a time of an operation of writing the write data by a predetermined data write unit of the first and second memory cell arrays,
the sense amplifier/write driver reads data relating to the data mask, and to supply the data to the error correcting circuit, and
the error correcting circuit generates an error correcting code, based on the write data and the read data relating to the data mask, and to supply the write data and the error correcting code to the sense amplifier/write driver.

7. The memory system of claim 2, further comprising a reference circuit,
wherein the sense amplifier/write driver senses the first and second memory cell arrays by using the reference circuit, when a first operation mode selection signal is received, and to sense the first memory cell array by using the second memory cell array, when a second operation mode selection signal is received.

8. The memory system of claim 7, wherein the sense amplifier/write driver includes a switch circuit configured to electrically connect, when receiving the first operation mode selection signal, the reference circuit and the first memory cell array or the second memory cell array, and to electrically connect, when receiving the second operation mode selection signal, the first memory cell array and the second memory cell array.

9. The memory system of claim 7, wherein, at a time of the second operation mode, the first and second memory cell arrays store complementary data.

10. The memory system of claim 1, wherein each of the first and second memory cell arrays includes a plurality of memory cells configured to be able to store data.

11. The memory system of claim 10, wherein the first and second memory cell arrays include the same number of the memory cells.

12. The memory system of claim 10, wherein the memory cell includes a variable resistance element.

13. The memory system of claim 10, wherein the memory cell is any one of an MRAM (Magnetic Random Access Memory), an FeRAM (Ferroelectric random access memory), a PCRAM (phase change random access memory), and a ReRAM (resistive random access memory).

14. A memory system comprising:
a first memory cell array and a second memory cell array each including a plurality of first memory cells and a plurality of second memory cells respectively, each of which stores data,
wherein in the first memory cell array each of the data is set at a first value, and in the second memory cell array each of the data is set at a second value which is a complementary value of the first value.

15. The memory system of claim 14, further comprising a control circuit which controls data of the first and second memory cell arrays,
wherein the control circuit sets, when receiving an initialization instruction, all of the plurality of the first memory cells at the first value, and set all of the plurality of the second memory cells at the second value.

16. The memory system of claim 15, further comprising a sense amplifier/write driver senses, in accordance with control of the control circuit, the data stored in the first memory cell array and the second memory cell array, and writes data in the first memory cell array and the second memory cell array.

17. The memory system of claim 16, wherein in an initialization operation of the first and the second memory cell arrays, the control circuit sets all of the plurality of the first memory cells and the second memory cells at the first value, and to set all of the plurality of the second memory cells at the second value.

18. The memory system of claim 17, wherein an operation of setting all of the plurality of the first memory cells and the second memory cells at the first value is executed by using a magnet.

19. The memory system of claim 16, further comprising an error correcting circuit generates an error correcting code, based on write data which is written in the first and the second memory cell arrays, and to supply the data and the error correcting code to the sense amplifier/write driver.

20. The memory system of claim 19, wherein in a case where a data mask for executing no write operation of data at a predetermined area of the first and second memory cell arrays is included in the write data at a time of an operation of writing the write data by a predetermined data write unit of the first and second memory cell arrays,
the sense amplifier/write driver which reads data relating to the data mask, and supplies the data to the error correcting circuit, and
the error correcting circuit generates an error correcting code, based on the write data and the read data relating to the data mask, and supplies the write data and the error correcting code to the sense amplifier/write driver.
